(19) United States
(12) Patent Application Publication
(10) Pub. No.: US 2017/0110331 A1
(43) Pub. Date: Apr. 20, 2017

(54) Methods for Forming Semiconductor Devices

(71) Applicant: Infineon Technologies Austria AG, Villach (AT)

(72) Inventors: Ravi Keshav Joshi, Villach (AT); Johannes Baumgartl, Riegersdorf (AT); Georg Ehrentraut, Villach (AT); Petra Fischer, Wernberg (AT); Richard Gaisberger, Velden (AT); Christoph Gruber, Wernberg (AT); Martin Poelzl, Ossiach (AT); Juergen Steinbrenner, Noetsch (AT)

(21) Appl. No.: 15/293,533

(22) Filed: Oct. 14, 2016

(30) Foreign Application Priority Data
Oct. 15, 2015 (DE) 102015117582.7

(51) Int. Cl. H01L 21/308; H01L 29/10; H01L 29/40; H01L 29/78; H01L 29/66; H01L 29/423; H01L 21/3063; H01L 29/739

(52) U.S. Cl. CPC H01L 21/3088; H01L 21/3085; H01L 21/3086; H01L 21/3081; H01L 21/3063; H01L 29/1095; H01L 29/7396; H01L 29/7813; H01L 29/66348; H01L 29/66734; H01L 29/4236; H01L 29/401

(57) ABSTRACT

A method for forming a semiconductor device includes etching, in a masked etching process, through a layer stack located on a surface of a semiconductor substrate to expose the semiconductor substrate at unmasked regions of the layer stack. The method further includes etching, in a selective etching process, at least a first layer of the layer stack located adjacently to the semiconductor substrate. A second layer of the layer stack is less etched or non-etched compared to the selective etching of the first layer of the layer stack, such that the first layer of the layer stack is laterally etched back between the semiconductor substrate and the second layer of the layer stack. The method further includes growing semiconductor material on regions of the surface of the semiconductor substrate exposed after the selective etching process.

### TECHNICAL FIELD

Embodiments relate to forming holes and/or trenches, and in particular to methods for forming semiconductor devices.

### BACKGROUND

Metal oxide semiconductor field effect transistor (MOSFET) technologies which rely on lithography tools or self-aligned concepts may produce structures falling outside of tolerance limits. For example, it may be difficult to control the pitch of the trenches, and to provide accurate alignment of trenches and contact holes. Furthermore, it may be difficult to obtain perfect contact hole overlay with respect to a body (e.g. a transistor body region) or to control a distance between contact holes and a transistor gate, for example. These challenges may lead to poor control over device structures and/or to increases in process costs and production time.

### SUMMARY

It is a demand to provide concepts for forming semiconductor devices with increased reliability and/or with less complexity.

Some embodiments relate to a method for forming a semiconductor device. The method comprises etching, in a masked etching process, through a layer stack located on a surface of a semiconductor substrate to expose the semiconductor substrate at unmasked regions of the layer stack. The method further comprises etching, in a selective etching process, at least a first layer of the layer stack located adjacently to the semiconductor substrate. A second layer of the layer stack is less etched or non-etched compared to the selective etching of the first layer of the layer stack, such that the first layer of the layer stack is laterally etched back between the semiconductor substrate and the second layer of the layer stack. The method further comprises growing semiconductor material on regions of the surface of the semiconductor substrate exposed after the selective etching process.

Some embodiments relate to a method for forming a semiconductor device. The method comprises forming a first group of trenches and a second group of trenches at a semiconductor substrate. The trenches of the first group of trenches have a first vertical dimension and the trenches of the second group of trenches have a second different vertical dimension. The first group of trenches are formed by a trench-etching process and the second group of trenches are formed by a removal process different from the trench-etching process. The forming of the first group of trenches and the second group of trenches comprises using only one lithographic process.

Those skilled in the art will recognize additional features and advantages upon reading the following detailed description and on viewing the accompanying drawings.

### BRIEF DESCRIPTION OF THE FIGURES

Some embodiments of apparatuses and/or methods will be described in the following by way of example only, and with reference to the accompanying figures, in which

FIG. 1 shows a flow chart of a method for forming a semiconductor device:

FIGS. 2A to 2I show schematic illustrations of a method for forming a semiconductor device;

FIG. 3 shows a flow chart of a further method for forming a semiconductor device according to an embodiment; and

FIG. 4 shows a schematic illustration of a lithographic process for forming a first group of trenches and a second group of trenches.

### DETAILED DESCRIPTION

Various example embodiments will now be described more fully with reference to the accompanying drawings in which some example embodiments are illustrated. In the figures, the thicknesses of lines, layers and/or regions may be exaggerated for clarity.

Accordingly, while example embodiments are capable of various modifications and alternative forms, embodiments thereof are shown by way of example in the figures and will herein be described in detail. It should be understood, however, that there is no intent to limit example embodiments to the particular forms disclosed, but on the contrary, example embodiments are to cover all modifications, equivalents, and alternatives falling within the scope of the disclosure. Like numbers refer to like or similar elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent.” etc.).

The terminology used herein is for the purpose of describing particular embodiments only and is not intended to be limiting of example embodiments. As used herein, the singular forms “a.” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art. However, should the present disclosure give a specific meaning to a term deviating from a meaning commonly understood by one of ordinary skill, this meaning is to be taken into account in the specific context this definition is given herein.

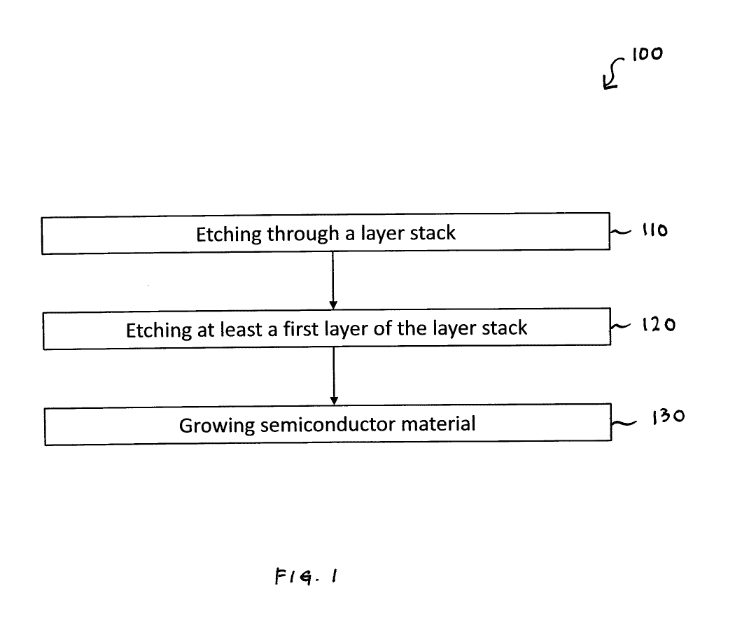

FIG. 1 shows a flow chart of a method 100 for forming a semiconductor device according to an embodiment.

The method 100 comprises etching 110, in a masked etching process, through a layer stack located on a surface of a semiconductor substrate to expose the semiconductor substrate at unmasked regions of the layer stack.

The method further comprises etching 120, in a selective etching process, at least a first layer of the layer stack located adjacently to the semiconductor substrate. A second layer of the layer stack is less etched or non-etched compared to the selective etching of the first layer of the layer stack, such that the first layer of the layer stack is laterally etched back between the semiconductor substrate and the second layer of the layer stack.

The method further comprises growing 130 semiconductor material on regions of the surface of the semiconductor substrate exposed after the selective etching process.

Due to the first layer being laterally etched back between the semiconductor substrate and the second layer of the layer stack, and the semiconductor material being grown on the regions exposed after the selective etching process, the number of processes and/or a complexity of processes used for forming a contact hole and a trench structure may be reduced. For example, the number of processes and/or the complexity of processes used for defining a size of a contact hole and/or an alignment of contact holes with respect to neighboring trench structures may be reduced.

The layer stack may include at least a first layer (or film) and at least a second layer (or film) which is different to the first layer, for example. The first layer of the layer stack may be located directly adjacently to the surface of the semiconductor substrate. The second layer may be located directly adjacently to the first layer of the layer stack. For example, the first layer of the layer stack may be located between the surface of the semiconductor substrate and the second layer of the layer stack.

The first layer of the layer stack may be a silicon oxide layer, for example. A maximal (or largest) thickness of the first layer of the layer stack may lie between 200 nm and 600 nm (or e.g. between 300 nm and 500 nm), for example. For example, a maximal (or largest) thickness of the first layer of the layer stack may be about 400 nm. The thickness of the first layer of the layer stack may be a thickness measured in a direction substantially perpendicularly to the lateral surface of the semiconductor substrate, for example.

The second layer of the layer stack may be a silicon nitride (SNIT) layer, for example. The second layer of the layer stack may be deposited on (e.g. directly on) the first layer of the layer stack, for example. A maximal (or largest) thickness of the second layer of the layer stack may lie between 100 nm and 400 nm (or e.g. between 100 nm and 300 nm), for example. For example, a maximal (or largest) thickness of the second layer of the layer stack may be a thickness depending on the etching selectivity with respect to the first layer of the layer stack (e.g. about 270 nm, or e.g. greater than or less than 270 nm. The thickness of the second layer of the layer stack may be a thickness measured in a direction substantially perpendicularly to the lateral surface of the semiconductor substrate, for example.

The first layer of the layer stack and the second layer of the layer stack may cover (e.g. more than 40%, or e.g. more than 50%, or e.g. more than 80% of) a main lateral surface of the semiconductor substrate. The main (lateral) surface of the semiconductor substrate may be a substantially even plane (e.g. neglecting unevenness of the semiconductor structure due to the manufacturing process and trenches). For example, the lateral dimension of the main surface of the substrate may be more than 100 times larger (or more than 1000 times or more than 10000 times) than a maximal height of structures on the main surface. For example, the lateral dimension of the main surface of the substrate may be more than 100 times larger (or more than 1000 times or more than 10000 times) than a maximal vertical thickness of the semiconductor substrate, for example.

The masked etching process 110 may be a lithographic process. The deposited films (e.g. the first layer of the layer stack and the second layer of the layer stack 201 may be structured on the semiconductor substrate (e.g. the wafer) with an isotropic (dry) plasma etch by using a lithography mask of appropriate pitch, for example. The lithography mask may include masked and unmasked regions for forming the desired pattern or features to be etched through the layer stack.

The masked etching process 110 may lead to the forming of a plurality of etched-through regions (e.g. etched-through trenches) in the layer stack, in regions where the first layer of the layer stack and the second layer of the layer stack are removed at unmasked regions of the layer stack. The etched-through regions (or trenches) may extend vertically from a surface of the second layer of the layer stack to a surface of the semiconductor substrate exposed by the removal of the first layer of the layer stack and the second layer of the layer stack during the masked etching process 110.

The selective etching process 120 may be an etching process in which the second layer of the layer stack is less etched or non-etched compared to the selective etching of the first layer of the layer stack. For example, an etch rate of the first layer of the layer stack may be larger and/or faster (e.g. more than 10 times, or e.g. more than 100 times, or e.g. more than 1000 times larger and/or faster) than an etch rate of the second layer of the layer stack during the selective etching process.

The selective etching (e.g. an isotropic wet etch) of the first layer of the layer stack with respect to the second layer of the layer stack may result in the first layer of the layer stack being laterally etched back between the semiconductor substrate and the second layer of the layer stack. For example, the exposed regions of the semiconductor substrate are increased below the second layer of the layer stack (e.g. in the cavity regions between the second layer of the layer stack and the semiconductor substrate).

Due to the selective etching process 120, the first layer of the layer stack may form a negative cavity (e.g. an undercutting cavity) under the second layer of the layer stack due to the first layer of the layer stack being etched faster or more than the second layer of the layer stack over the course of the selective etching process 120. A difference between a maximum lateral dimension of an etched-back portion of the first layer of the layer stack and a lateral dimension of the less etched or non-etched second layer of the layer stack (between neighboring unmasked regions) may define a separation distance between a trench from a first group of trenches and a neighboring trench from a second group of trenches to be formed.

It may be understood, that other than the material selections provided herein, other material selections or combinations of the first layer of the layer stack and the second layer of the layer stack may also be possible, as long as they allow the first layer of the layer stack to be selectively etched with respect to the second layer of the layer stack, for example.

The semiconductor material may be grown 130 epitaxially on the exposed regions after the selective etching process 120, for example. The semiconductor material may be grown 130 such that the grown semiconductor material may be located adjacently to etched-back portions of the first layer of the layer stack (e.g. to portions of the first layer of the layer stack which remain on the semiconductor surface after the selective etching 120) and to the second layer of the layer stack remaining on the semiconductor substrate after the selective etching process 120. For example, the grown semiconductor material may fill (at least partially) the etched-through trenches (or holes) within the layer stack. Additionally, the grown semiconductor material may fill (at least partially) and/or be formed in the cavities under the second layer of the layer stack. The grown semiconductor material may be located between neighboring etched-back portions of the first layer of the layer stack and/or between neighboring portions of the second layer of the layer stack, for example.

Optionally, the semiconductor material grown on the semiconductor substrate may be the same as (e.g. to consist of the same materials, or chemical elements as) the semiconductor substrate material. For example, the semiconductor substrate material may be a silicon-based semiconductor substrate material (e.g. silicon), a silicon carbide-based semiconductor substrate material, a gallium arsenide-based semiconductor substrate material or a gallium nitride-based semiconductor substrate material. The semiconductor material may be chosen such that the grown semiconductor material and the semiconductor substrate may be easily etched in a single etching process to form a first group of trenches, for example.

Optionally, the thickness of the epitaxially grown semiconductor material (e.g. the Si film) may be controlled such that the grown semiconductor material protrudes out of the SNIT openings without overgrowing on it.

Alternatively or optionally, the thickness of the epitaxially grown semiconductor material (e.g. the Si film) may be controlled such that the grown semiconductor material protrudes minimally or does not protrude out of the SNIT openings.

Alternatively or optionally, the epitaxially grown semiconductor material may be grown thick enough to cover the second layer of the layer stack (e.g. the SNIT film), and may be polished back to the level of the second layer of the layer stack (e.g. the SNIT level) after the growth of the semiconductor material. Either option (or method) may be used to maintain the critical dimensions of the device, for example.

If the thickness of the epitaxially grown semiconductor material (e.g. the Si film) is controlled such that the grown semiconductor material protrudes minimally or does not protrude out of the SNIT openings, a trench-etching process may be carried out (directly) after the growth of the semiconductor material. For example, in the trench-etching process, the (epitaxially grown) semiconductor material (located on the unmasked regions) and the semiconductor substrate may be etched (simultaneously or in separate etching processes) to form a first group of trenches extending (vertically) through the grown semiconductor material and the semiconductor substrate. The second layer of the layer stack (e.g. the SNIT film) may provide a sacrificial layer (or a resistant mask) against the etching of the grown semiconductor material and the semiconductor substrate and/or to gain selective etching of the grown semiconductor material (e.g. silicon) and the semiconductor substrate (e.g. silicon). In other words, the second layer of the layer stack may be less etched or non-etched with respect to the etching of the grown semiconductor material and the semiconductor substrate.

The first group of trenches may be trench-etched to a desired thickness (or depth). For example, the first group of trenches may be etched such that a maximum vertical dimension (or vertical height) of the trenches of the first group of trenches may lie between 500 nm and 80 μm (or e.g. may lie between 500 nm and 2 μm, or e.g. may be greater than 10 μm, or e.g. may be greater than 30 μm), for example.

A maximum (or largest) lateral dimension of the trenches of the first group of may be less than 300 nm (or e.g. may lie between 100 nm and 300 nm, or e.g. between 200 nm and 300 nm), for example. The lateral dimension of the trenches of the first group of trenches formed in the semiconductor substrate may be based on (e.g. substantially controlled by, or e.g. mainly set, or e.g. may be adjusted based on, or e.g. equal to) a lateral dimension of the etched-through regions in the layer stack formed by the etching through the layer stack in the masked etching process. For example, the lateral dimension of the trenches of the first group of trenches formed in the semiconductor substrate may vary by less than +/−1%, (or e.g. less than +/−5%, or less than +/−10%) from the lateral dimension of the etched-through regions in the layer stack.

The method may further include removing the layer stack (e.g. the first layer of the layer stack and the second layer of the layer stack) after the growth of the semiconductor material to obtain a second group of trenches (e.g. contact holes) adjacent to the grown semiconductor material. Both the first layer of the layer stack and the second layer of the layer stack may be removed by wet etching in the same or different etching processes, for example. However, the etching of the first layer of the layer stack and the second layer of the layer stack may be selective with respect to the grown semiconductor material and the semiconductor substrate. For example, the grown semiconductor material and the semiconductor substrate may remain after the etching of the first layer of the layer stack and the second layer of the layer stack.

A vertical dimension of the trenches of the second group of trenches may be less than a vertical dimension of the trenches of the first group of trenches, for example. For example, the second group of trenches may be formed on or at the surface of the semiconductor substrate. However, the trenches of the first group of trenches may be etched into or extend through the semiconductor substrate, for example. A vertical dimension of the trenches of the second group of trenches formed by the removing of the first layer of the layer stack and the filler material may lie between 100 nm and 500 nm, for example.

A lateral dimension of the trenches of the second group of trenches may be based on (e.g. substantially controlled by, or e.g. mainly set, or e.g. may be adjusted based on, or e.g. equal to) a lateral dimension of etched-back portions of the first layer of the layer stack after the selective etching process. For example, the lateral dimension of the trenches of the second group of trenches may vary by less than +/−1%, (or e.g. less than +/−5%, or less than +/−10%) from a lateral dimension of etched-back portions of the first layer of the layer stack.

Alternatively, instead of carrying out the trench-etching directly after the growth of the semiconductor material (e.g. in the case of the thickness of the epitaxially grown semiconductor material being controlled such that the semiconductor material protrudes minimally or does not protrude out of the SNIT openings), the method may include removing at least the second layer of the layer stack remaining on the semiconductor substrate (directly) after growing the semiconductor material (e.g. before trench-etching).

The second layer of the layer stack (e.g. the SNIT film) may be selectively etched away (or removed) with respect to grown semiconductor material (e.g. silicon) and with respect to the first layer of the layer stack (e.g. the oxide film) located or lying underneath the second layer of the layer stack (e.g. the SNIT film), for example. For example, the grown semiconductor material and the first layer of the layer stack may be non-etched or less etched during (or after) the removal of the second layer of the layer stack.

The method 100 may further include depositing filler material on portions of the first layer of the layer stack and on portions of the grown semiconductor material remaining on the surface of the semiconductor substrate after removing at least the second layer of the layer stack. For example, the deposited filler material may replace the removed second layer of the layer stack or fill the regions left exposed or empty by the removal of the second layer of the layer stack. Optionally, the filler material and the first layer of the layer stack may be identical materials. For example, the filler material and the first layer of the layer stack may include or may consist of the same material (e.g. silicon oxide). The filler material may be chosen to be identical to the first layer of the layer stack such that the filler material and the first layer of the layer stack may be removed easily (e.g. in a single etching process) to obtain the second group of trenches, for example. Alternatively, the filler material may be a material that offers selectivity for etching the semiconductor substrate (e.g. silicon). For example, the filler material may be a photoresist or carbon.

The method 100 may further include, optionally, polishing the filler material and the semiconductor material (e.g. by chemical-mechanical polishing CMP) to expose laterally (e.g. in a lateral direction, dx) alternating regions of filler material and regions of grown semiconductor material on a substantially even (or level) surface, substantially parallel to the main lateral surface of the semiconductor substrate.

In subsequent trench-etching process to form a first group of trenches, the (epitaxially grown) semiconductor material and the semiconductor substrate may be etched to form a first group of trenches extending through the grown semiconductor material and the semiconductor substrate. Due to the replacing of the SNIT film with oxide filler material (e.g. by removing the second layer of the layer stack in and depositing filler material), selective trench-etching of the grown semiconductor material and the semiconductor substrate may be made easier with respect to oxide (e.g. the filler material).

The method 100 may further include removing the first layer of the layer stack and the filler material to obtain a second group of trenches adjacent to the grown semiconductor material (e.g. at positions of etched-back portions of the first layer of the layer stack remaining after the selective etching) after the trench-etching (or e.g. after forming the first group of trenches). The first layer of the layer stack and the filler material may be removed by wet etching, for example. The removal of the first layer of the layer stack and the filler material (e.g. the oxide removal) may result in a self-aligned trench and a contact hole (or a plurality of self-aligned trenches and a plurality of self-aligned contact holes) being formed, for example.

The method 100 may include forming the first group of trenches and the second group of trenches, such that a separation distance between a trench from the first group of trenches and a neighboring trench from the second group of trenches may be based on (e.g. substantially controlled by, or e.g. mainly set, or e.g. may be adjusted based on, or e.g. equal to) a difference between a maximum lateral dimension of an etched-back portion of the first layer of the layer stack and a lateral dimension of the less etched or non-etched second layer of the layer stack between neighboring unmasked regions. For example, a separation distance between a trench from the first group of trenches and a neighboring trench from the second group of trenches may vary by less than +/−1%, (or e.g. less than +/−5%, or less than +/−10%) from a difference between a maximum lateral dimension of an etched-back portion of the first layer of the layer stack and a lateral dimension of the less etched or non-etched second layer of the layer stack.

Due to the first group of trenches and the second group of trenches being formed using self-aligned process, the masked etching process 110 may be the only lithographic process used for forming the first group of trenches having the first vertical dimension and the second group of trenches having the second different vertical dimension at the semiconductor substrate, for example.

The group of transistor structures to be formed may include a metal oxide semiconductor field effect transistor device (MOSFET) structure, an insulated gate bipolar transistor device (IGBT) structure, a charge compensation transistor device structure, a diode device structure and a thyristor device structure, for example. The group of transistor structures may be vertical transistor structures having a (first) source/drain or emitter/collector contact and a gate contact are arranged or located at a main lateral surface (e.g. a front side surface) of the semiconductor substrate, and a (second) source/drain or emitter/collector contact located at an opposite lateral surface (e.g. a back side surface) of the semiconductor substrate.

Each semiconductor device may be a power semiconductor device having a breakdown voltage or blocking voltage of more than more than 10V (e.g. a breakdown voltage of 10 V, 20 V or 50V), more than 100 V (e.g. a breakdown voltage of 200 V, 300 V, 400V or 500V) or more than 500 V (e.g. a breakdown voltage of 600 V, 700 V, 800V or 1000V) or more than 1000 V (e.g. a breakdown voltage of 1200 V, 1500 V, 1700V or 2000V or 3300V) or more than 6000 V, for example. A highest blocking voltage for IGBTs may be (3300V or 6000V, for example.

Silicon technology is based on the shrinkage of device dimensions and thereby the boost in its performance according to Moore's law. Power MOSFETs are already in the sub-micron or even nano regimes. For a given voltage class (the break down voltage the device should withstand without fail) of MOSFETs, certain minimum Si area is a prerequisite, for example. The performance boost is not achieved unless one optimizes or perfects the pitch of the trenches, and/or accurate alignment of trenches and contact holes, and/or over-lay of contact hole with respect to body, and/or its distance from the gate oxide, and/or gate electrode conductivity (metal gate instead of poly gate), for example. This may lead to numerous processes per layer which are more and more difficult even with advanced lithography tools to secure the proper alignment and over-lays within the given tolerance limits, for example.

MOSFET technologies rely on overlay lithography tools or on the self-aligned concept based on the selective deposition and/or etching one film (oxide, nitride, silicon or carbon) with respect to another. A problem associated with such a method is, various dimensions of the films should not fall out of tolerance limits. If they do, the concept does not deliver the beneficial results. Thus, on one hand, processes should be finely controlled, and on the other hand numerous post process control methodologies have to be incorporated, for example. They not only cost in terms of capital investment but also in terms of process cost and may lead to increase in the production time.

Some self-aligned concepts (for forming the trenches and contact holes) may suffer a direct influence on numerous previous processes which is cumbersome for the production. The method 100 reduces these complexities and achieves the required performance boost by uses a self-aligned concept to tune a distance between trench and contact hole, for example. The method 100 uses processes such as selective etching and/or selective epitaxy etc. to put forth a methodology to form a self-aligned trench and contact hole. The technique not only aligns the contact hole with respect to its adjacent trench automatically but also offers the possibility to define the size of contact hole according to requirements. In addition, the number of processes which may have an influence on the dimensional accuracy of the pitch and/or variation of trench to contact hole distance may be kept to a minimum, for example.

The method describes herein may be used to produce trenches and/or contact holes in microelectromechanical systems (MEMs) and/or for producing field effect transistor structures such as metal oxide semiconductor field effect transistor structures and/or compensation structures such as CoolMOS transistor structures, for example.

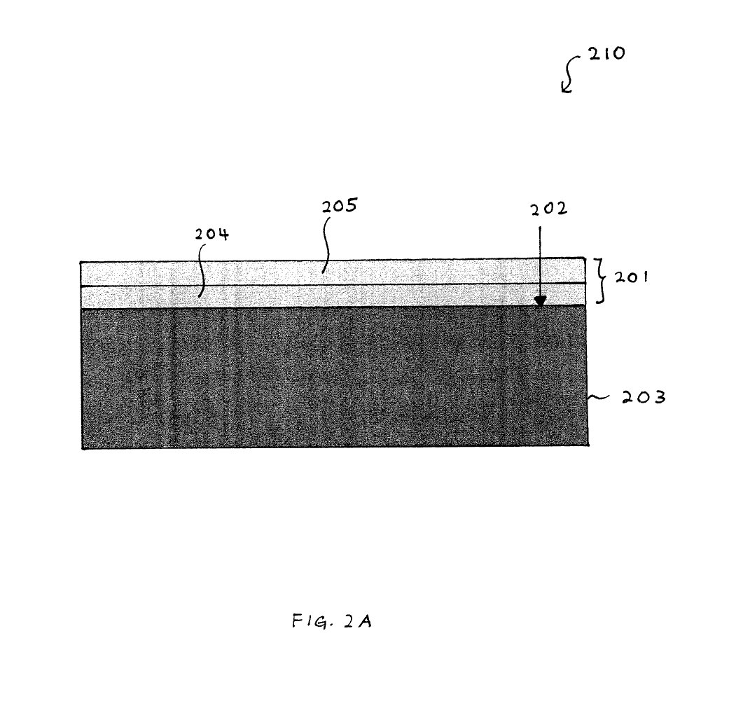

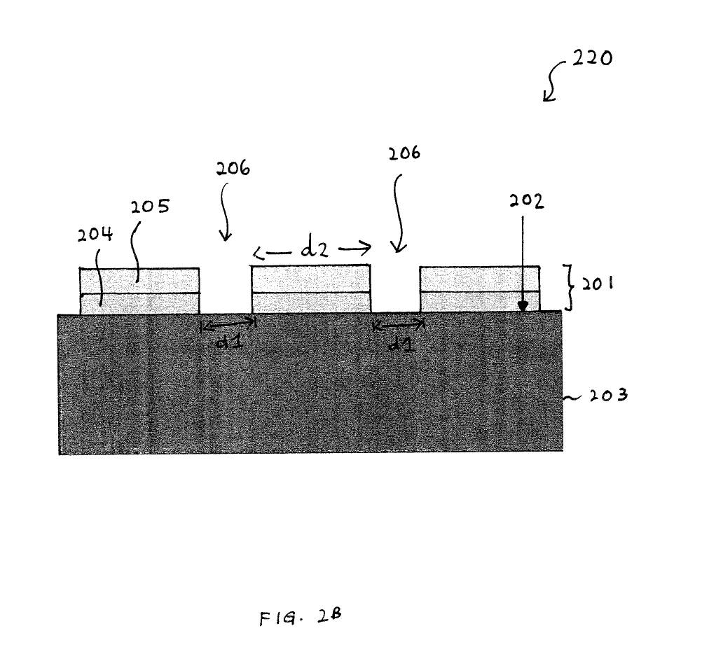

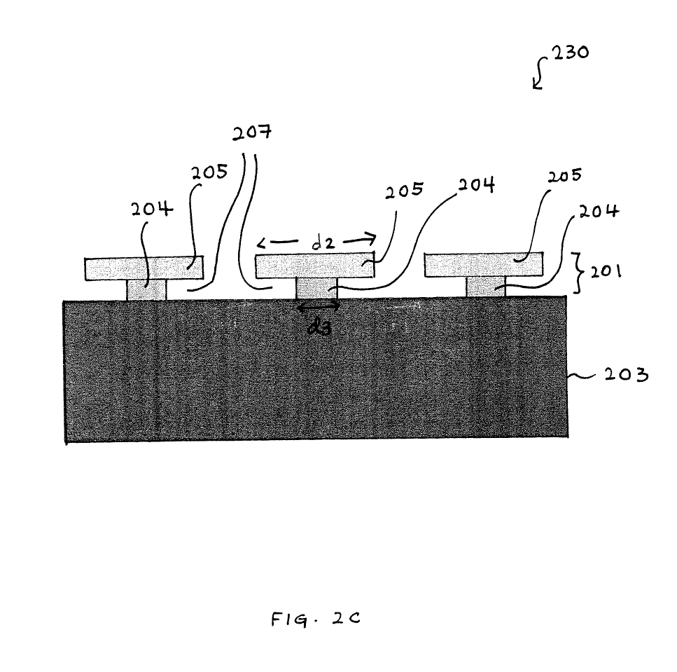

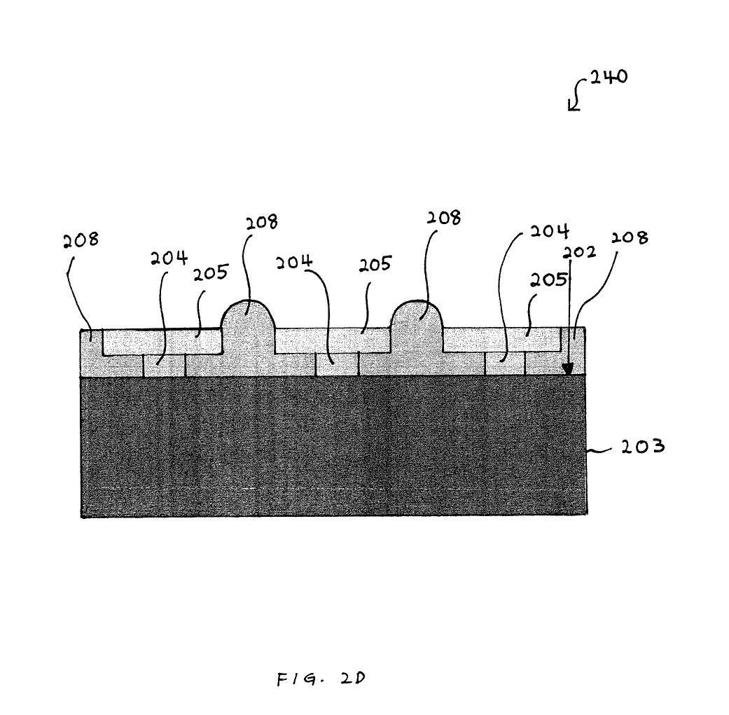

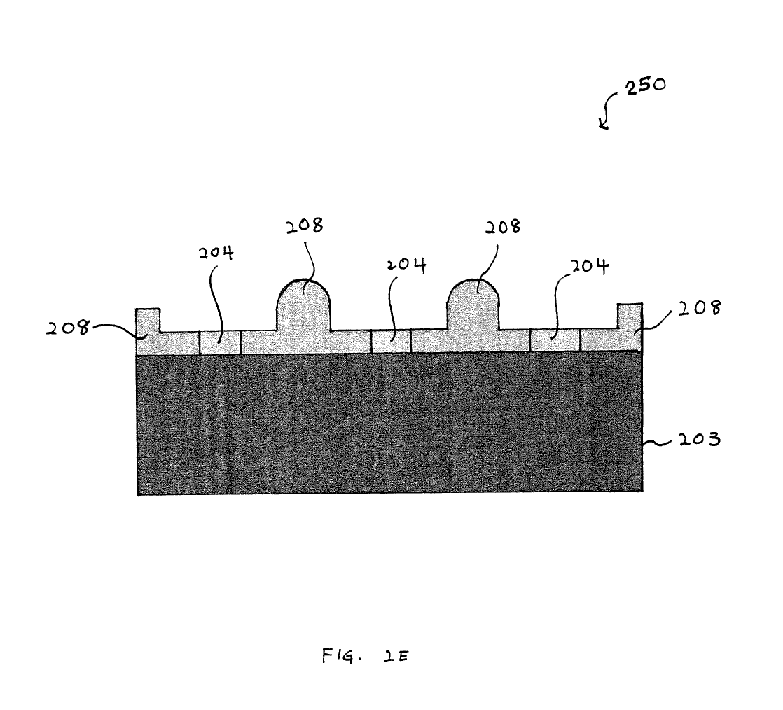

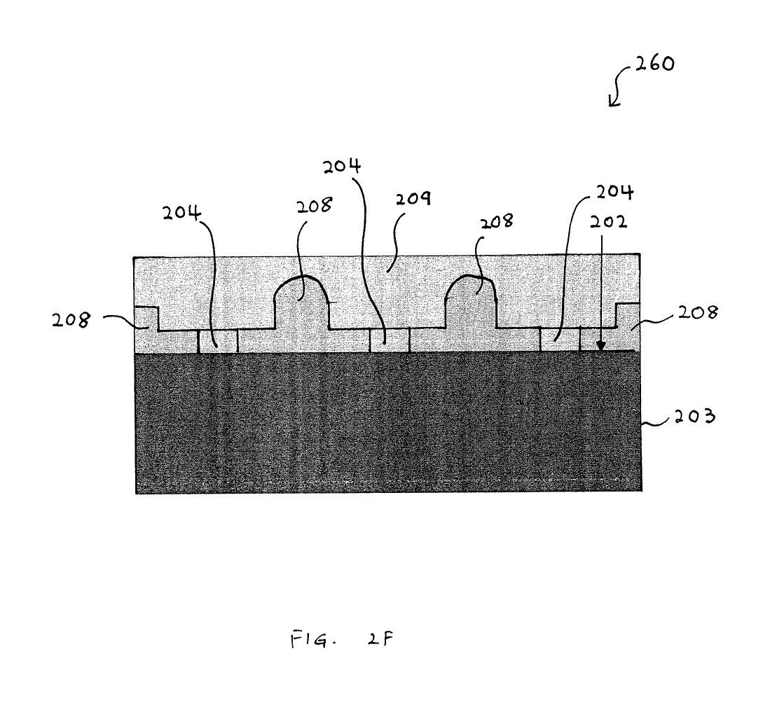

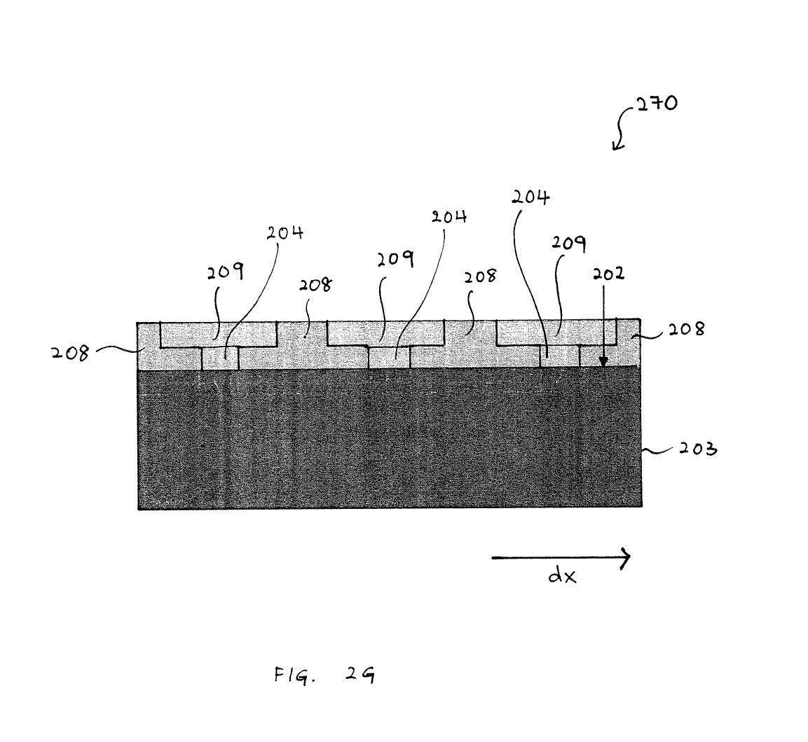

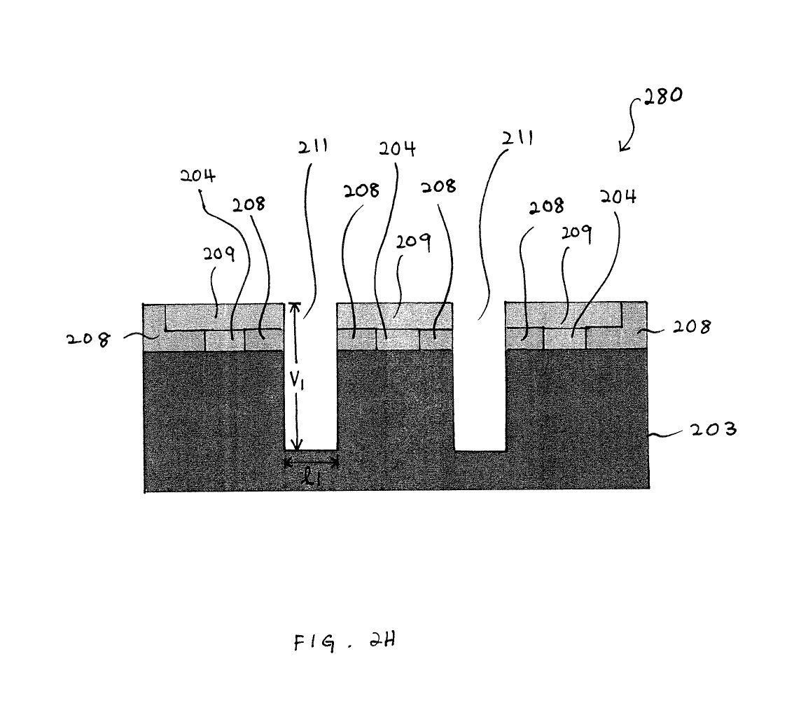

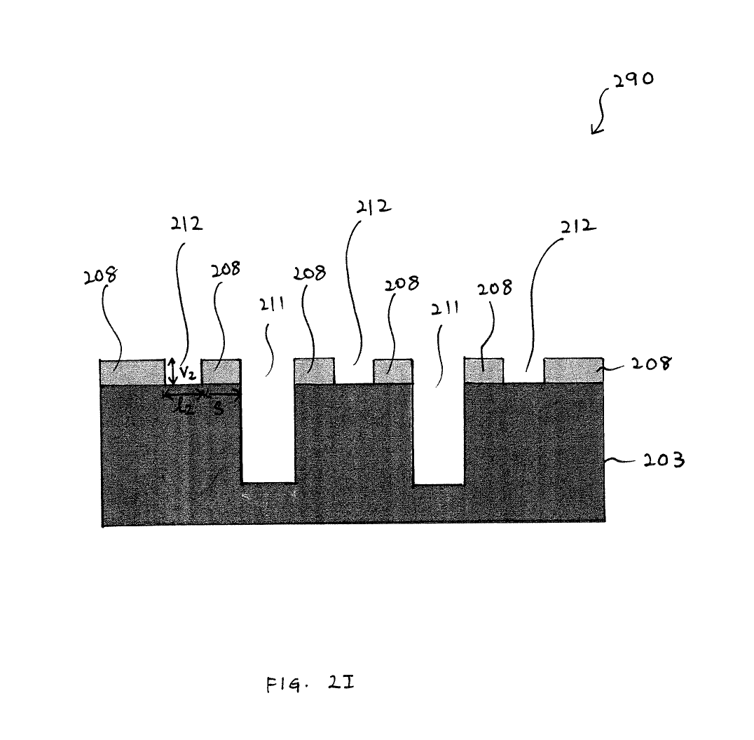

FIGS. 2A to 2I show schematic illustrations of a method for forming a semiconductor device according to an embodiment. The method described with respect to FIGS. 2A to 2I may be similar to the method described in connection with FIG. 1.

As shown in FIG. 2A, the method may include forming 210 a layer stack 201 (e.g. a hard mask) on a surface 202 of a semiconductor substrate 203.

The layer stack 201 may include at least two layers (e.g. two or more layers). A first layer 204 of the layer stack 201 may be (or may comprise or consist of) a first material. A second layer 205 of the layer stack 201 may be (or may comprise or consist of) a second material. The second material of the second layer 205 of the layer stack 201 may be different from the first material of the first layer 204 of the layer stack 201.

The first layer 204 of the layer stack 201 may be a silicon oxide layer, for example. For example, the first layer 204 of the layer stack 201 may be grown by wafer oxidation on (e.g. directly on) or over the surface 202 of the semiconductor substrate 203. For example, the semiconductor substrate (which may be a silicon Si wafer, for example), may be oxidized to form the oxide layer (e.g. a silicon oxide layer), for example. A maximal (or largest) thickness of the first layer 204 of the layer stack 201 may lie between 200 nm and 600 nm (or e.g. between 300 nm and 500 nm), for example.

The second layer 205 of the layer stack 201 may be a silicon nitride (SNIT) layer, for example. The second layer 205 of the layer stack 201 may be deposited on (e.g. directly on) the first layer 204 of the layer stack 201, for example. The second layer 205 of the layer stack 201 may cover completely (e.g. may be formed on more than 80%, or e.g. more than 90%, or e.g. more than 99% of the lateral surface of) the first layer 204 of the layer stack 201. A maximal (or largest) thickness of the second layer 205 of the layer stack 201 may lie between 100 nm and 400 nm (or e.g. between 100 nm and 300 nm), for example.

The main surface 202 of the semiconductor substrate 203 may be a basically horizontal surface extending laterally. The main surface 202 may be a surface of the semiconductor substrate towards metal layers, insulation layers and/or passivation layers to be formed on top of the surface 202 of the semiconductor substrate or a surface of one of these layers. For example, the main surface 202 may be a side of the semiconductor substrate 203 at which active elements of the semiconductor device are to be formed. For example, in a power semiconductor chip, the main surface 202 may be a chip front side, which may be a side of the chip at which a first source/drain region and a gate region are formed, and a chip back side may be a side of the chip at which a second source/drain region is formed. For example, more complex structures may be located at the chip front side (e.g. the main surface 202) than at the chip back side.

As shown in FIG. 2B, the method may include etching 220, in a masked etching process, through the layer stack 201 located on the surface 202 of the semiconductor substrate 203 to expose the semiconductor substrate 203 at unmasked regions of the layer stack 201.

The masked etching process 220 may include (or may be) a lithographic process. The two deposited films (e.g. the first layer 204 of the layer stack 201 and the second layer 205 of the layer stack 201 may be structured on the semiconductor substrate 203 (e.g. the wafer) with an isotropic (dry) plasma etch by using a lithography mask of appropriate pitch. The lithography mask may include masked and unmasked regions of a desired pattern of features to be reproduced in the hard mask. The pattern or features of the may be etched through the layer stack 201 based on the lithography mask, for example.

The masked etching process 220 may lead to the forming of a plurality of etched-through regions 206 (e.g. etched-through trenches or holes) in the layer stack 201. The plurality of etched-through regions 206 may be regions where the first layer 204 of the layer stack 201 and the second layer 205 of the layer stack 201 are removed at during the masked etching process. The etched-through regions 206 (or trenches) may extend vertically from a surface of the second layer 205 of the layer stack 201 to a surface 202 of the semiconductor substrate 203 exposed by the removal of the first layer 204 of the layer stack 201 and the second layer 205 of the layer stack 201 during the masked etching process 220.

A maximum (or largest) lateral dimension, d1, of the etched-through regions 206 may be less than 300 nm (or e.g. may lie between 100 nm and 300 nm, or e.g. between 200 nm and 300 nm), for example. A maximum (or largest) lateral dimension, d1, of the etched-through regions 206 may define a lateral dimension of trenches of a group (e.g. a first group) of trenches (e.g. gate trenches) to be formed at the semiconductor substrate 203.

A maximum (or largest) lateral dimension, d2, of a plurality of remaining portions of the layer stack 201 after the masked etching process may be less than 5 μm (or e.g. may lie between 300 nm and 2 μm, or e.g. between 400 nm and 600 nm), for example.

The masked etching process described in connection with FIG. 2B, and the selective etching process described in connection with FIG. 2C, may serve to structure the hard mask used for subsequent process.

As shown in FIG. 2C, the method may further include etching 230, in a selective etching process, at least the first layer 204 of the layer stack 201 located adjacently to the semiconductor substrate 203.

The semiconductor substrate 203 (or wafer) may be subjected to a (selective) isotropic (oxide) wet etch to etch the oxide film (e.g. the first layer 204 of the layer stack 201) beneath the SNIT film (e.g. the second layer 205 of the layer stack 201) to form at least one negative cavity under the SNIT film. The wet etch may be a hydrofluoric acid buffer (HFB) etch and may be carried out for about 20 minutes, for example.

The selective etching process may be an etching process in which the second layer 205 of the layer stack 201 is less etched or non-etched compared to the selective etching of the first layer 204 of the layer stack 201. For example, a ratio of an etch rate of the first layer 204 of the layer stack 201 to an etch rate of the second layer 205 of the layer stack 201 may be greater than 10:1 (or e.g. greater than 100:1, or e.g. greater than 1000:1) over greater than 80% (or e.g. greater than 90%, or e.g. greater than 99%) of the selective etching process.

The selective etch of the first layer 204 of the layer stack 201 with respect to the second layer 205 of the layer stack 201 may result in the first layer 204 of the layer stack 201 being laterally etched back (e.g. undercut) between the semiconductor substrate 203 and the second layer 205 of the layer stack 201. For example, the first layer 204 of the layer stack 201 may form a negative cavity 207 (e.g. an undercutting cavity) under the second layer 205 of the layer stack 201.

The first layer 204 of the layer stack 201 may be selectively etched such that a maximal (largest) lateral dimension, d3, of the first layer 204 of the layer stack 201 is smaller than (or e.g. less than 80% of or e.g. less than 60% of, or e.g. less than 50% of) a maximal (largest) lateral dimension, d2, of the second layer 205 of the layer stack 201 after the selective etching process, for example.

A maximum (largest) lateral dimension, d3, of the etched-back portions of the first layer 204 of the layer stack 201 (e.g. portions of the first layer 204 of the layer stack 201 which remain on the semiconductor surface 202 after the selective etching) may define a lateral dimension of trenches of a second group of trenches (e.g. contact holes) to be formed in the semiconductor substrate 203. For example, the maximum (largest) lateral dimension, d3, of an etched-back portion of the first layer 204 of the layer stack 201 may be less than 300 nm (or e.g. may lie between 100 nm and 300 nm, or e.g. between 200 nm and 300 nm), for example.

A difference (e.g. d2−d3) between a maximum lateral dimension, d3, of an etched-back portion of the first layer 204 of the layer stack 201 and a lateral dimension, d2, of the less etched or non-etched second layer 205 of the layer stack 201 between neighboring unmasked regions may define a separation distance between a trench from the first group of trenches and a neighboring trench (e.g. a contact hole) from a second group of trenches (e.g. contact holes). The length of time for which the selective etching process is carried out, and/or the width of the left over oxide film (e.g. d3) may define a size of a contact hole and/or a distance of a contact hole from two adjacent trenches, for example.

A maximum (or largest) difference (e.g. d2−d3) between a maximum lateral dimension, d3, of an etched-back portion of the first layer 204 of the layer stack 201 and a lateral dimension, d2, of the less etched or non-etched second layer 205 of the layer stack 201 may lie between 50 nm and 300 nm (or e.g. between 50 nm and 200 nm), for example.

As shown in FIG. 2D, the method may further include growing 240 semiconductor material 208 on regions of (or on) the surface 202 of the semiconductor substrate 203 exposed after the selective etching process 230.

The semiconductor material 208 may be grown epitaxially on the exposed regions of the surface 202 of the semiconductor substrate 203 after the selective etching process, for example. The semiconductor material 208 may be grown such that the grown semiconductor material 208 may be located adjacently (e.g. laterally adjacently and/or directly adjacently) to etched-back portions of the first layer 204 of the layer stack and adjacently (e.g. laterally adjacently and/or directly adjacently) to the second layer 205 of the layer stack remaining on the semiconductor substrate after the selective etching process. For example, the grown semiconductor material may fill the etched-through trenches 206 (or holes) within the layer stack 201. For example, the grown semiconductor material 208 may fill (at least partially) and/or be formed in the cavities (or undercut regions) between the second layer 205 of the layer stack 201 and the semiconductor substrate 203. Furthermore, the grown semiconductor material 208 may be located between neighboring etched-back portions of the first layer 204 of the layer stack 201 and/or between neighboring portions of the second layer 205 of the layer stack 201, for example.

The epitaxial growth of the semiconductor material 208 (e.g. a silicon film) may be carried out such that the grown semiconductor material 208 reaches (or is of) a certain thickness. This may lead to the filling of the negative space (or cavity 207) formed by the wet (selective) etch, and the filling of the gaps between the SNIT films 205.

The thickness of the epitaxially grown semiconductor material 208 (e.g. the Si film) may be controlled such that the semiconductor material 208 film protrudes out of SNIT openings without overgrowing on it. Alternatively, the epitaxially grown semiconductor material 208 may be grown thick enough to cover the second layer 205 of the layer stack 201 (e.g. the SNIT film), and may be polished back to the level of the second layer 205 of the layer stack 201 (e.g. the SNIT level) after the growth of the semiconductor material 208. Either option (or method) may be used to maintain the critical dimensions of the device, for example.

Optionally, the method may include controlling a doping concentration of the semiconductor material 208 during the growth of the semiconductor material 208 to form a body region of at least one transistor structure of the semiconductor device to be formed. For example, during the selective epitaxial growth of the semiconductor material 208, the necessary dose of the doping of the body region may be incorporated. This may help to tune the body alignment with respect to a source-body contact to be formed, which may not usually be trivial. Furthermore, various process steps, such as implantation and annealing, to induce the necessary body doping may be saved (or avoided).

As shown in FIG. 2E, after growing the semiconductor material 208, the method may include removing 250 at least the second layer 205 of the layer stack 201 remaining on the semiconductor substrate.

The second layer 205 of the layer stack 201 (e.g. the SNIT film) may be selectively etched away with respect to semiconductor material 208 (e.g. silicon) and the first layer 204 of the layer stack 201 (e.g. the oxide film) located or lying underneath the second layer 205 of the layer stack 201 (e.g. the SNIT film), for example. The second layer 205 of the layer stack 201 may be selectively etched (e.g. in an SNIT etch) such that the grown semiconductor material 208 (e.g. silicon) and the first layer 204 of the layer stack 201 (e.g. the oxide film) remain on the semiconductor substrate 203 (e.g. are not etched, or e.g. less etched) after the selective etching of the second layer 205 of the layer stack 201. For example, a ratio of an etch rate of the second layer 205 of the layer stack 201 to an etch rate of the semiconductor substrate 203 may be greater than 10:1 (or e.g. greater than 100:1, or e.g. greater than 1000:1). For example, a ratio of an etch rate of the second layer 205 of the layer stack 201 to an etch rate of the first layer 204 of the layer stack 201 may be greater than 10:1 (or e.g. greater than 100:1, or e.g. greater than 1000:1).

As shown in FIG. 2F, the method may further include depositing 260 filler material 209 (e.g. in an oxide deposition) on portions of the first layer 204 of the layer stack 201 and on portions of the grown semiconductor material 208 remaining on the surface 202 of the semiconductor substrate 203 after removing at least the second layer of the layer stack 201.

Optionally, the filler material 209 and the first layer 204 of the layer stack 201 may be identical materials. For example, the filler material 209 and the first layer 204 of the layer stack 201 may include or may consist of the same material (e.g. silicon oxide). Alternatively, the filler material 209 may be a material that offers selectivity for etching the semiconductor substrate 203 (e.g. silicon) and the (epitaxially grown) semiconductor material 208. For example, the filler material may be a photoresist or carbon.

The filler material 209 may be deposited to a thickness such that the filler material 209 may embed or cover (optionally completely embed or completely cover) the first layer 204 of the layer stack 201 and the grown semiconductor material 208, for example. Alternatively, the filler material 209 may be deposited to a thickness such that the filler material 209 may be located between portions of grown semiconductor material 208 without covering or embedding the grown semiconductor material 208, for example.

As shown in FIG. 2G, after depositing the filler material, the method may further include polishing 270 the filler material 209 and the grown semiconductor material 208 (e.g. by chemical-mechanical polishing CMP the oxide) to expose laterally (e.g. in a lateral direction, dx) alternating regions of filler material 209 and regions of grown semiconductor material 208 on a substantially even surface.

The filler material 209 and the grown semiconductor material 208 may be polished back chemical-mechanically to show alternate (or alternating) strips (or regions) of epitaxially grown silicon 208 and deposited oxide 209, for example.

As shown in FIG. 2H, after polishing 270 the filler material 209 and the grown semiconductor material 208, the method may include etching 280, in a trench-etching process, the (epitaxially grown) semiconductor material 208 and the semiconductor substrate 203 to form a first group of trenches 211 extending through the grown semiconductor material 208 and the semiconductor substrate 203. In the trench-etching process, portions of the grown semiconductor material 208 located on the unmasked regions (or on the etched-through regions 206 formed by the masked etching process) may be removed. Furthermore, portions of the semiconductor substrate 203 located under the portions of the grown semiconductor material located on the unmasked regions may be removed. Portions of the grown semiconductor material 208 beyond on the semiconductor substrate 203, but outside the unmasked regions or etched-through regions (e.g. grown semiconductor material 208 located in the cavities formed due to lateral etch-back during the selective etch) may remain on the semiconductor substrate 203 after the trench-etching process.

Due to the replacing of the SNIIT film with oxide (e.g. by removing the second layer of the layer stack in 250 and depositing filler material in 260), selective trench-etching of the grown semiconductor material 208 and the semiconductor substrate 203 may be made easier with respect to oxide (e.g. the filler material 209). It may be understood that a certain minimum thickness of the SNIT film (e.g. the second layer of the layer stack deposited in 210) is necessary to offer enough thickness to form the hard mask formed from (oxide) filler material 209, to form the first group of trenches.

The first group of trenches 211 may be (vertically) trench-etched to a desired thickness. For example, the first group of trenches 211 may be etched such that a (maximum or largest) vertical dimension, v1, of the trenches of the first group of trenches 211 may lie between 500 nm and 2 μm, for example.

A lateral dimension, L1, of the trenches of the first group of trenches 211 formed in the semiconductor substrate 203 may be based on (e.g. substantially controlled by, or e.g. mainly set, or e.g. may be adjusted based on, or e.g. equal to) a lateral dimension, d1, of the etched-through regions 206 in the layer stack 201 formed by the etching through the layer stack 201 in the masked etching process in 220. For example, the lateral dimension. L1, of the trenches of the first group of trenches 211 formed in the semiconductor substrate 203 may vary by less than +/−1%, (or e.g. less than +/−5%, or less than +/−10%) from the lateral dimension, d1 of the etched-through regions 206 in the layer stack 201.

A maximum (or largest) lateral dimension, L1, of the trenches of the first group of trenches 211 formed in the semiconductor substrate 203 may be less than 300 nm (or e.g. may lie between 100 nm and 300 nm, or e.g. between 200 nm and 300 nm), for example.

A maximum pitch between neighboring trenches of the first group of trenches 211 may be less than 1 μm, or e.g. less than 800 nm, for example.

As shown in FIG. 2I, the method may further include removing 290 the first layer 204 of the layer stack 201 and the filler material 209 to obtain a second group of trenches 212 (e.g. contact holes) adjacent to the grown semiconductor material 208 (e.g. at positions of etched-back portions of the first layer of the layer stack remaining after the selective etching). The first layer 204 of the layer stack 201 and the filler material 209 may be removed by wet etching (e.g. an oxide removal process), for example.

Due to the removal by selective etching of the first layer 204 of the layer stack 201 and the filler material 209 with respect to the grown semiconductor material 208 and the semiconductor substrate 203, the grown semiconductor material 208 and the semiconductor substrate 203 may be not etched or less etched compared to the etching of the first layer 204 of the layer stack 201 and the filler material 209, for example. For example, For example, a ratio of an etch rate of the first layer 204 of the layer stack 201 and the filler material 209 to an etch rate of the grown semiconductor material 208 and the semiconductor substrate 203 may be greater than 10:1 (or e.g. greater than 100:1, or e.g. greater than 1000:1).

A vertical dimension, v2, of the trenches of the second group of trenches 212 formed by the removing of the first layer 204 of the layer stack and the filler material 209 may lie between 100 nm and 500 nm, for example.

A lateral dimension, L2, of the trenches of the second group of trenches 212 may be based on (e.g. substantially controlled by, or e.g. mainly set, or e.g. may be adjusted based on, or e.g. equal to) a lateral dimension, d3, of etched-back portions of the first layer 204 of the layer stack after the selective etching process in 230. For example, the lateral dimension, L2, of the trenches of the second group of trenches 212 may vary by less than +/−1%, (or e.g. less than +/−5%, or less than +/−10%) from the lateral dimension, d3, of etched-back portions of the first layer 204 of the layer stack due to the masked etching process.

The first group of trenches 211 and the second group of trenches 212 may be formed such that a separation distance, s, between a trench 211 from the first group of trenches 211 and a neighboring trench 212 from the second group of trenches 212 may be based on (e.g. substantially controlled by, or e.g. mainly set, or e.g. may be adjusted based on, or e.g. equal to) a difference (e.g. d2−d3) between a maximum lateral dimension, d3, of an etched-back portion of the first layer 204 of the layer stack 201 and a lateral dimension, d2, of the less etched or non-etched second layer 205 of the layer stack 201 (shown in FIG. 2C). A maximum separation distance s, between a trench 211 from the first group of trenches 211 and a neighboring trench 212 from the second group of trenches 212 may lie between 100 nm and 300 nm (or e.g. between 100 nm and 200 nm), for example.

The removal 290 of the first layer 204 of the layer stack 201 and the filler material 209 (e.g. the oxide removal) may provide at least one self-aligned trench 211 and at least one contact hole 212, for example. For example, the wet etching of the oxide (in 230) may be the only critical step needed to control the dimensional accuracy of trench 211 and contact hole 212, for example. All other processes may be easy to control the critical dimensions, for example. Furthermore, the masked etching process (in 220) is the only lithographic process used for forming the first group of trenches 211 having the first vertical dimension and the second group of trenches 212 having the second different vertical dimension at the semiconductor substrate 203, for example.

The method may further include forming further doping regions in the semiconductor substrate. For example, the method may include forming a plurality of first source/drain or collector/emitter regions (e.g. by introducing dopants) in regions of the semiconductor substrate 203 adjacent to the second group of trenches 212.

The method may further include depositing electrically conductive contact material in the second group of trenches to form (a plurality of first) source/drain or emitter/collector contact of the transistor structures of the semiconductor device.

The method may further include depositing a gate insulation layer and a gate contact material in the first group of trenches to form gates of the transistor structures of the semiconductor device.

The semiconductor substrate 203 may include (or may provide) a (continuous) drift region of the transistor structures. For example, the drift region may be a portion of the semiconductor substrate located between a back side surface of the semiconductor substrate 203 and the front side surface 202 of the semiconductor substrate 203. For example, the each trench of the second group of trenches 212 may extend vertically from a body region of a transistor structure (formed by the grown semiconductor material 208) towards (or to) a drift region of the transistor structure located in the semiconductor substrate 203.

The method may further include forming a second source/drain region (of a MOSFET) or a second collector/emitter region (of an IGBT) at the back side surface (opposite to the front side surface 202) of the semiconductor substrate 203.

The method may further include forming a backside metallization layer on the back side surface of the semiconductor substrate 203. The backside metallization may be arranged directly adjacently to the second source/drain region or collector/emitter region, for example.

The body region of the transistor structure may be located between the first source/drain region of the transistor structure and the drift region of the transistor structure. The body region of the transistor structure may have a first conductivity type (e.g. p doped). The first source/drain region of the transistor structure located at the front side surface 202 of the semiconductor substrate may have a second conductivity type (e.g. n++ doped), for example. The drift region of the transistor structure may be located between the body region of the transistor structure and a second source/drain region of the transistor structure located towards the back side surface of the semiconductor substrate 203. The drift region of the transistor structure may have a second conductivity type (e.g. n doped). The second source/drain region of the transistor structure may have a second conductivity type (e.g. n++ doped), for example.

In the case of the transistor structure being a MOSFET structure, the second source/drain region of the transistor structure may be located at the back side surface of the semiconductor substrate 203.

In the case of the transistor structure being an IGBT structure, the drift region of the FET structure may be located between the body region of the transistor structure and a second emitter/collector region of the transistor structure located at the back side surface of the semiconductor substrate 203. The second emitter/collector region of the transistor structure may have a first conductivity type (e.g. p+ doped). Optionally, a highly doped field stop region having the second conductivity type (e.g. n+ doped) may be located between the drift region and the second emitter/collector region of the transistor.

A region comprising the first conductivity type may be a p-doped region (e.g. caused by incorporating aluminum ions or boron ions) or an n-doped region (e.g. caused by incorporating nitrogen ions, phosphor ions or arsenic ions). Consequently, the second conductivity type indicates an opposite n-doped region or p-doped region. In other words, the first conductivity type may indicate an p-doping and the second conductivity type may indicate a n-doping or vice-versa.

It may be understood that all the incorporated films or layers, such as the first layer 204 (the oxide), the filler material 209, and the second layer 205 (the SNIT), may be variably replaced with respect to each other or with resist film and/or polysilicon and/or with various types of carbon hard masks. The materials may be selected or used to facilitate the selective growth and/or selective etching with respect to each other.

The methods described in connection with FIG. 1 and FIGS. 2A to 2I may use a lithographically structure silicon oxide (e.g. SiO₂) and SNIT stack. The methods may use a dry etch and a subsequent wet etch of silicon oxide to define a width of trenches to be formed. The methods may include silicon epitaxial growth after the dry etch and the wet etch. The methods may further include SiO₂ deposition and CMP until the SNIT level after the silicon epitaxial growth. The methods may further include trench-etching after the SiO₂ deposition and CMP. The methods may further include mask removal and thus contact hole formation after the trench-etching.

A need for two lithography steps for two different types of trenches may be eliminated, for example. Furthermore, a need for very precise epitaxial growth may be eliminated, for example. Furthermore, with the SiO₂ wet etch, dimensions of the trenches and the contact holes may be precisely controlled.

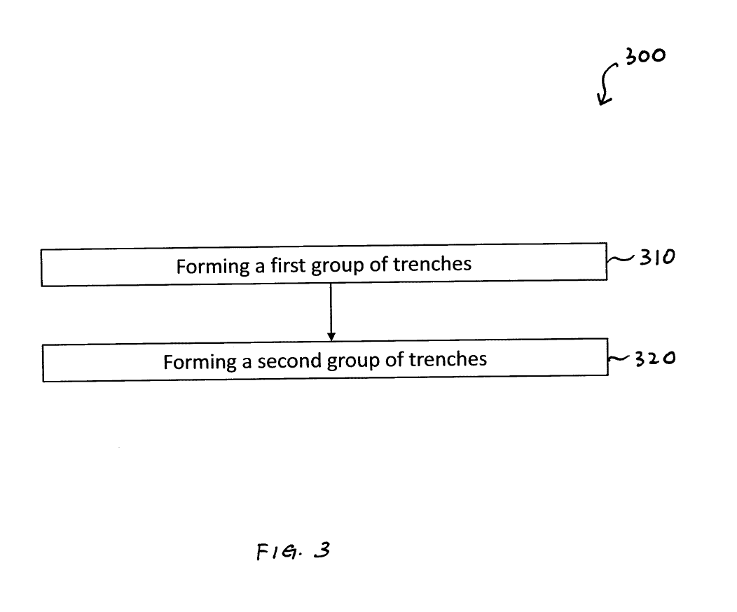

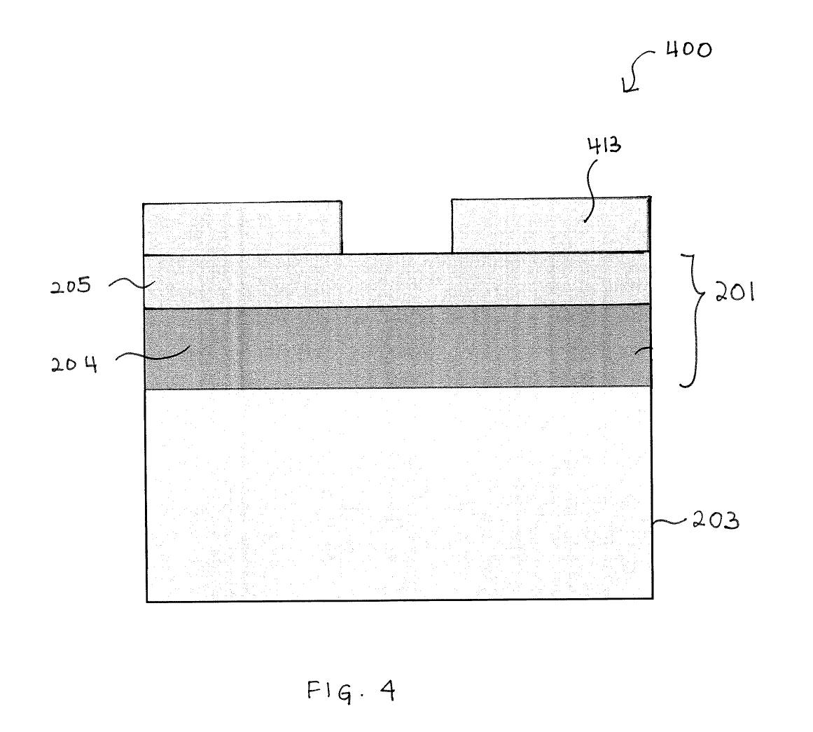

More details and aspects are mentioned in connection with the embodiments described above or below. The embodiments shown in FIGS. 2A to 2I may comprise one or more optional additional features corresponding to one or more aspects mentioned in connection with the proposed concept or one or more embodiments described above (e.g. FIG. 1) or below (e.g. FIGS. 3 to 4).

FIG. 3 shows a flow chart of a method 300 for forming a semiconductor device according to an embodiment.

The method 300 comprises forming 310, 320 a first group of trenches and a second group of trenches at a semiconductor substrate.

The trenches of the first group of trenches have a first vertical dimension and the trenches of the second group of trenches have a second different vertical dimension.

The first group of trenches are formed by a trench-etching process and the second group of trenches are formed by a removal process different from the trench-etching process. The forming 310, 320 of the first group of trenches and the second group of trenches comprises using only one lithographic process.

Due to the forming 310, 320 of the first group of trenches and the second group of trenches comprising using only one lithographic process, the number of processes and/or a complexity of process used for forming a contact hole and a trench structure may be reduced. For example, the number of processes and/or the complexity of processes used for defining a size of a contact hole and/or and alignment of contact holes with respect to neighboring trench structures may be reduced.

The trench-etching process and the removal process may be separate (e.g. different) chemical etching processes carried out at different times, for example. For example, the removal process for forming the second group of trenches may be carried out after the trench-etching process for forming the first group of trenches has been completed. For example, the trench-etching process may be similar to the trench-etching process described in connection with FIG. 2H. For example, the removal process may be similar to the removal process described in connection with FIG. 2I.

A (maximum or largest) vertical dimension, v1, of the trenches of the first group of trenches 211 may lie between 500 nm and 2 μm, for example.

A (maximum or largest) vertical dimension, v2, of the trenches of the second group of trenches 212 may lie between 100 nm and 500 nm, for example.

The method 300 may be similar to the method described in connection with FIG. 1 and the method described in connection with FIGS. 2A to 2I. For example, the method 300 may include one or more or all of the processes described in connection with FIG. 1 and/or the method described in connection with FIGS. 2A to 2I.

More details and aspects are mentioned in connection with the embodiments described above or below. The embodiments shown in FIG. 3 may comprise one or more optional additional features corresponding to one or more aspects mentioned in connection with the proposed concept or one or more embodiments described above (e.g. FIGS. 1 to 2I) or below (FIG. 4).

FIG. 4 shows a schematic illustration 400 of the only lithographic process for forming a first group of trenches and the second group of trenches as described in connection with FIG. 1, FIGS. 2A to 2 J, and FIG. 3.

FIG. 4 shows the etching, in a masked etching process, through the layer stack 201 located on a surface of the semiconductor substrate 203 to expose the semiconductor substrate 203 at unmasked regions of the layer stack 201.

The lithography mask 413 may include patterns to provide masked and unmasked regions at the layer stack 201. The lithography mask pattern may be used to form the desired pattern or features to be etched through the layer stack 201, for example.

More details and aspects are mentioned in connection with the embodiments described above or below. The embodiments shown in FIG. 4 may comprise one or more optional additional features corresponding to one or more aspects mentioned in connection with the proposed concept or one or more embodiments described above (e.g. FIGS. 1 to 3) or below.

Various examples relate to a concept for forming a self-aligned contact hole with respect to its adjacent trenches, for example. Various examples relate to a method to develop a self-aligned contact with respect to a trench using only one lithography step which offers good dimensional accuracy and less dependency on various process steps, for example. Various examples relate to a method to define the size of contact hole as well as its distance from its adjacent trenches in one step, for example. Various examples relate to a method for epitaxial growth of a (transistor) body with uniform doping concentration aligned to a trench, for example. Various examples relate to how a self-aligned trench and a contact hole may be formed, for example.

Aspects and features (e.g. the semiconductor substrate, the first layer of the layer stack, the second layer of the layer stack, the masked etching process, the selective etching process, the grown semiconductor material, the trench-etching process, the first group of trenches, the removing of the first layer of the layer stack and depositing filler material) mentioned in connection with one or more specific examples may be combined with one or more of the other examples.

Example embodiments may further provide a computer program having a program code for performing one of the above methods, when the computer program is executed on a computer or processor. A person of skill in the art would readily recognize that acts of various above-described methods may be performed by programmed computers. Herein, some example embodiments are also intended to cover program storage devices, e.g., digital data storage media, which are machine or computer readable and encode machine-executable or computer-executable programs of instructions, wherein the instructions perform some or all of the acts of the above-described methods. The program storage devices may be, e.g., digital memories, magnetic storage media such as magnetic disks and magnetic tapes, hard drives, or optically readable digital data storage media. Further example embodiments are also intended to cover computers programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. It will thus be appreciated that those skilled in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and embodiments of the disclosure, as well as specific examples thereof, are intended to encompass equivalents thereof.

Functional blocks denoted as “means for . . . ” (performing a certain function) shall be understood as functional blocks comprising circuitry that is configured to perform a certain function, respectively. Hence, a “means for s.th.” may as well be understood as a “means configured to or suited for s.th.”. A means configured to perform a certain function does, hence, not imply that such means necessarily is performing the function (at a given time instant).

It should be appreciated by those skilled in the art that any block diagrams herein represent conceptual views of illustrative circuitry embodying the principles of the disclosure. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Furthermore, the following claims are hereby incorporated into the Detailed Description, where each claim may stand on its own as a separate embodiment. While each claim may stand on its own as a separate embodiment, it is to be noted that—although a dependent claim may refer in the claims to a specific combination with one or more other claims—other embodiments may also include a combination of the dependent claim with the subject matter of each other dependent or independent claim. Such combinations are proposed herein unless it is stated that a specific combination is not intended. Furthermore, it is intended to include also features of a claim to any other independent claim even if this claim is not directly made dependent to the independent claim.

It is further to be noted that methods disclosed in the specification or in the claims may be implemented by a device having means for performing each of the respective acts of these methods.

Further, it is to be understood that the disclosure of multiple acts or functions disclosed in the specification or claims may not be construed as to be within the specific order. Therefore, the disclosure of multiple acts or functions will not limit these to a particular order unless such acts or functions are not interchangeable for technical reasons. Furthermore, in some embodiments a single act may include or may be broken into multiple sub acts. Such sub acts may be included and part of the disclosure of this single act unless explicitly excluded.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method for forming a semiconductor device, the method comprising:
etching, in a masked etching process, through a layer stack located on a surface of a semiconductor substrate to expose the semiconductor substrate at unmasked regions of the layer stack;
etching, in a selective etching process, at least a first layer of the layer stack located adjacent to the semiconductor substrate, wherein a second layer of the layer stack is less etched or non-etched compared to the selective etching of the first layer of the layer stack, such that the first layer of the layer stack is laterally etched back between the semiconductor substrate and the second layer of the layer stack; and
growing semiconductor material on regions of the surface of the semiconductor substrate exposed after the selective etching process.

2. The method of claim 1, further comprising:
controlling a doping concentration of the semiconductor material grown on the regions of the surface of the semiconductor substrate exposed after the selective etching process, so as to form a body region of at least one transistor structure of the semiconductor device.

3. The method of claim 1, wherein the first layer of the layer stack is a silicon oxide layer and wherein the second layer of the layer stack is a silicon nitride layer.

4. The method of claim 1, further comprising:
etching, in a trench-etching process, the semiconductor substrate and the semiconductor material grown on the regions of the surface of the semiconductor substrate exposed after the selective etching process, so as to form a first group of trenches extending through the grown semiconductor material and the semiconductor substrate.

5. The method of claim 4, wherein a vertical dimension of the trenches of the first group of trenches is in a range between 500 nm and 2 μm.

6. The method of claim 4, wherein a lateral dimension of the trenches of the first group of trenches formed in the semiconductor substrate is based on a lateral dimension of etched-through regions in the layer stack formed by the etching through the layer stack in the masked etching process.

7. The method of claim 4, further comprising:
depositing a gate insulation layer and a gate contact material in the first group of trenches so as to form gates of transistor structures of the semiconductor device.

8. The method of claim 1, further comprising:
removing the layer stack after growing the semiconductor material on the regions of the surface of the semiconductor substrate exposed after the selective etching process, so as to obtain a second group of trenches adjacent to the grown semiconductor material.

9. The method of claim 8, wherein a vertical dimension of the trenches of the second group of trenches is in a range between 100 nm and 500 nm.

10. The method of claim 8, wherein a lateral dimension of the trenches of the second group of trenches is based on a lateral dimension of etched-back portions of the first layer of the layer stack after the selective etching process.

11. The method of claim 8, further comprising:
depositing electrically conductive contact material in the second group of trenches so as to form source/drain or emitter/collector contacts of transistor structures of the semiconductor device.

12. The method of claim 1, further comprising:
forming a first group of trenches and a second group of trenches,
wherein a separation distance between a trench from the first group of trenches and a neighboring trench from the second group of trenches is based on a difference between a lateral dimension of an etched-back portion of the first layer of the layer stack and a lateral dimension of the less etched or non-etched second layer of the layer stack between neighboring unmasked regions.

13. The method of claim 1, further comprising:
removing, after growing the semiconductor material on the regions of the surface of the semiconductor substrate exposed after the selective etching process, at least the second layer of the layer stack remaining on the semiconductor substrate.

14. The method of claim 13, further comprising:
depositing filler material on portions of the first layer of the layer stack and on portions of the grown semiconductor material remaining on the surface of the semiconductor substrate after removing at least the second layer of the layer stack.

15. The method of claim 14, wherein the filler material and the first layer of the layer stack comprise identical materials.

16. The method of claim 14, further comprising:
polishing the filler material and the semiconductor material grown on the regions of the surface of the semiconductor substrate exposed after the selective etching process, so as to expose laterally alternating regions of the filler material and regions of the grown semiconductor material on a substantially even surface.

17. The method of claim 16, further comprising:
etching, in a trench-etching process, the semiconductor substrate and the semiconductor material grown on the regions of the surface of the semiconductor substrate exposed after the selective etching process, so as to form a first group of trenches extending through the grown semiconductor material and the semiconductor substrate after polishing the filler material and the grown semiconductor material.

18. The method of claim 14, further comprising:
removing the first layer of the layer stack and the filler material so as to obtain a second group of trenches adjacent to the grown semiconductor material.

19. The method of claim 1, wherein the masked etching process is the only lithographic process used for forming a first group of trenches having a first vertical dimension and a second group of trenches having a second different vertical dimension at the semiconductor substrate.

20. A method for forming a semiconductor device, the method comprising:
forming a first group of trenches and a second group of trenches at a semiconductor substrate, wherein the trenches of the first group of trenches have a first vertical dimension and the trenches of the second group of trenches have a second vertical dimension different than the first vertical dimension,
wherein the first group of trenches are formed by a trench-etching process and wherein the second group of trenches are formed by a removal process different from the trench-etching process, and
wherein the first group of trenches and the second group of trenches are formed using only one lithographic process.
